(19) United States
(12) Patent Application Publication
(10) Pub. No.: US 2016/0026472 A1
(43) Pub. Date: Jan. 28, 2016

(54) METHOD FOR IMPLEMENTING "INSTANT BOOT" IN A CUSTOMIZABLE SOC

(71) Applicant: Microsemi SoC Corporation, San Jose, CA (US)

(72) Inventors: Ciaran Murphy, Dublin (IE); Ian Bryant, Hook (GB); Gregory William Bakker, San Jose, CA (US); Timothy J. Morin, Copper Canyon, TX (US)

(73) Assignee: Microsemi SoC Corporation, San Jose, CA (US)

(21) Appl. No.: 14/790,248

(22) Filed: Jul. 2, 2015

Related U.S. Application Data
(60) Provisional application No. 62/027,262, filed on Jul. 22, 2014.

(51) Int. Cl. G06F 9/44; G06F 12/02; G11C 16/10; G06F 1/24

(52) U.S. Cl. CPC G06F 9/4401; G06F 1/24; G06F 12/0246; G11C 16/107; G06F 2212/7201

(57) ABSTRACT

A method for implementing an instant boot function in a customizable system on a chip (SoC) integrated circuit having an application specific integrated circuit portion including configuration registers includes providing a field programmable gate array fabric on the SoC, providing non-volatile memory cells on the SoC, and initializing the configuration registers using data from the non-volatile memory cells during a system reset mode of operation of the integrated circuit.

### BACKGROUND OF THE INVENTION

This application claims the benefit of U.S. Provisional Patent Application No. 62/027,262 for “Method for Implementing “Instant Boot” in a Customizable SoC” filed Jul. 22, 2014, the contents of which are incorporated in this disclosure by reference in their entirety.

### FIELD OF THE INVENTION

The present invention relates to user-programmable integrated circuit technology. More particularly, the present invention relates to non-volatile-memory (NVM)-based field programmable gate arrays (FPGAs) and system on chip (SoC) devices.

FPGAs and SoC devices that use NVM, such as Flash, SONOS, or other NVM-based FPGAs and SoC devices, are known to have an advantage over SRAM-based FPGAs regarding their ability to be “Instant On”. This means that they are instantaneously configured according to the user's specific requirements. However, in devices containing a combination of a configurable ASIC block (such as a microcontroller subsystem where the configuration of clocks, resets, peripherals is performed by system configuration registers), and a NVM-based FPGA fabric, the historical approach to configuration of the ASIC block portion has been to provide a set of volatile configuration registers, which are programmed by a processor to the user's required configuration by firmware which executes on the processor after negation of system reset.

### DESCRIPTION OF RELATED ART

The previous approaches to configuring a configurable processor-based microcontroller subsystem have been to use user boot firmware to write to system registers after the processor is released from reset in order to configure them to be specific to the user's system-specific requirements. An example of this is the SmartFusion® device available from Microsemi SoC Corporation, which contains an FPGA fabric and an ARM® Cortex®-M3 based microcontroller subsystem (MSS), with a number of communications peripherals. Certain aspects of this MSS are configurable, such as the configuration of which input/output (IO) pads of the device are allocated to each peripheral. In this device, it is necessary for boot firmware to write to the system registers controlling the selection of multiplexers, which allocates IO pads to the various peripherals.

### SUMMARY

The present invention uses memory cells configured using NVM technology, associated with the FPGA fabric, to initialize the configuration registers of the application specific integrated circuit (ASIC) portion of the device asynchronously during system reset. In this way, both the FPGA fabric and the configurable elements of the ASIC block are pre-configured to the user's requirements when the system reset negates. This obviates the need for boot code to configure the ASIC block registers. It also reduces the startup time of the system.

Further details and advantages of the invention will become clear upon reading the following detailed description in conjunction with the accompanying drawing figures, wherein like parts are designated with like reference numerals throughout.

### BRIEF DESCRIPTION OF THE DRAWINGS

FIG. 1 is a block diagram of an illustrative RW-F register in accordance with one aspect of the present invention.

FIG. 2 is a block diagram of an illustrative RW-P register in accordance with one aspect of the present invention.

FIG. 3 is a block diagram of an illustrative RN-F register in accordance with one aspect of the present invention.

FIG. 4 is a block diagram of an illustrative RO-U register in accordance with one aspect of the present invention.

FIG. 5 is a block diagram of an illustrative RO-P register in accordance with one aspect of the present invention.

FIG. 6 is a block diagram showing an illustrative architecture for an SoC integrated circuit including the configuration registers of the present invention.

### DESCRIPTION OF THE INVENTION

Persons of ordinary skill in the art will realize that the following description of the present invention is illustrative only and not in any way limiting. Other embodiments of the invention will readily suggest themselves to such skilled persons.

To control aspects of the configuration of a digital subsystem within a device requires the use of registers, which are implemented as flip-flops. In a device comprising both a microcontroller subsystem and NVM-based storage elements, such as Flash or SONOS, without limitation, it is possible to use the NVM storage elements to asynchronously initialize (during system reset) the state of each digital register bit (flip-flop) to a value pre-programmed into the NVM bit. In this way, each system register already contains the user-specified configuration value as soon as the system exits system reset.

The present invention defines a number of types of system registers, which may be initialized in this way. These are summarized in the following table:

| Type | Function |
|---|---|
| RW-F | Control Register |
| | Writable and Readable setting output value with dynamic |
| | control |
| | Initialized by factory NVM bit |
| RW-P | Control Register |
| | Writable and Readable setting output value with dynamic |
| | control |
| | Initialized by FPGA fabric NVM bit |
| RN-F | Control Register |
| | Never readable or writable except in factory test mode |
| | Initialized by factory NVM bit |
| RO-U | Control Register |
| | Not writable; Readable only |
| | Initialized by user NVM bit |
| RO-P | Control Register |
| | Not writable; Readable only |
| | Initialized by FPGA fabric NVM bit |

The five register types in Table 1 use different classes of NVM bits and are employed by the different “users” of the particular device from silicon manufacture, through system designer through to end customer.

The manufacturer of the programmable SoC silicon device may require the ability to configure the device in certain modes for manufacturing test purposes. These modes would not be exposed to the system integrator or the end-user. To facilitate this, there is a class of programmable NVM bits called a factory NVM bit, which can only be programmed or erased in the factory of the FPGA manufacturer and requires access to pads on the silicon wafer, which are not accessible in a packaged device. In the description of the system register implementations described herein, this type of NVM bit is referred to as “F”. Certain system registers may be initialized by F NVM bits, which means that only the manufacturing facility can define the initial value of those registers.

The immediate customer of the SoC manufacturer (who integrates the device into his own application) is referred to here as the system integrator. The system integrator may desire to configure the device with certain settings (e.g. security-related) that it does not want its own customer (the end-user) to be able to modify. In order to facilitate this, there is a class of programmable NVM bits that can be locked to an authentication key defined by the system integrator. Because the customer of the system integrator (the end-user) will not have access to this key, it is not possible for the end user to override these configurations. In the description of the system register implementations described herein, this type of NVM bit is referred to as “U” (user NVM). Certain system registers may be initialized by U NVM bits, which mean that only the system integrator can define the initial value of those registers.

The end-user (i.e., the customer of the system integrator) may be able to make changes to the device, if desired. For example, the end user may desire to change certain device configurations within the limits allowed by the system integrator. In order to facilitate this, there is a class of programmable NVM bits that may be used by the end-user. This type of NVM bit is referred to as “P”. Certain system registers may be initialized by P NVM bits, which means that the end-user can define the initial value of those registers. It is the same type of NVM bit as is used in the FPGA fabric itself and so may be referred to as “fabric NVM”.

The RW-F register bits are used for control/configuration purposes. In factory test mode (i.e., manufacturing test mode of SoC device), the host processor of the SoC may write directly to these registers using write accesses from test software. However, in normal operation, these registers are automatically set to be initialized to a value determined by the SoC device manufacturer, from F NVM bits (programmed at the SoC manufacturer's facility and never re-programmed or erased). In normal mode, the host processor cannot overwrite the value stored in these register bits. The register value is always readable by the host processor, however, in both factory test mode and normal mode.

The RW-P registers are normally readable and writeable by the host processor of the SoC. Each RW-P register is initialized to the value specified by the value of a P NVM bit. However, each RW-P register bit is also associated with another register bit, called the “dynamic register”. If this register is zero, it prevents the RW-P bit from being writeable by the host processor. This is useful for applications where the end-user is concerned about unintended writes to the register from rogue software running on the host processor (e.g., resulting from single event upset (SEU) in a harsh operating environment, such as space). In this case, the value of the NVM bit is continuously loaded into the register bit (via the asynchronous set/clear of the flip flop) so that it will recover the correct value after the SEU.

If the dynamic register bit associated with the RW-P register is set, then the register bit is always writeable and readable by the host processor. If the device is not programmed (or erased), then the value loaded into the RW-P register during reset comes from a hardware default value which is determined by the design of the SoC silicon.

The RN-F type of register bit is intended only to be visible to software on the host processor in the manufacturing phase of the SoC device (i.e., only visible to manufacturing test software running on the host processor). In this factory test mode, the register bit is both writeable and readable by the processor. However, when not in factory test mode, the register is neither readable nor writeable by the software running on the processor of the SoC. The initial value of this register bit comes from an F NVM bit.

The RO-U type of register bit is intended for registers used by the system integrator. For example, it may be used for registers which specify security configuration of the device. The register bits are always readable by the host processor but never writeable. The initial value of the register comes from a U NVM bit.

The RO-P registers are used to implement registers which are intended to be readable, but not writeable, by the host processor during normal operation. The initial value comes from a P NVM bit (i.e., a fabric bit). In factory test mode (i.e., by the SoC silicon manufacturer), these registers may be overwritten by test software running on the host processor of the SoC.

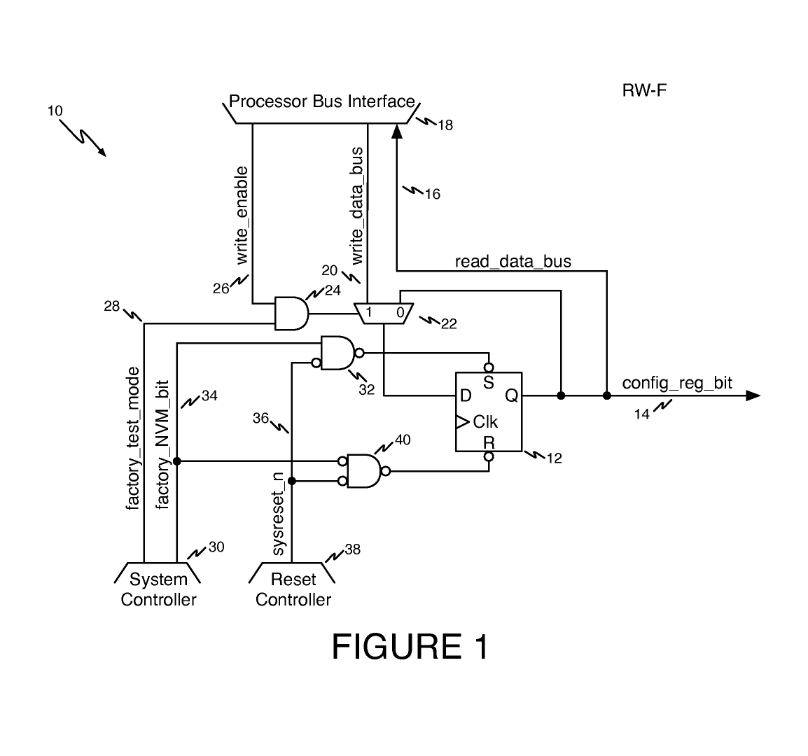

Referring now to FIG. 1, a block diagram shows an illustrative embodiment of an RW-F register 10 according to one aspect of the present invention. Register 10 is built around flip-flop 12, shown having a data input (D), a clock input (Clk), a set (S) and reset (R) inputs and an output (Q).

The output (Q) of the flip-flop 12 forms the configuration register bit (config_reg_bit) 14 and is coupled to a bit of a read_data signal 16 of the processor bus interface 18. A bit of a write_data_bus 20 is coupled to the data input (D) of flip-flop 12 through one data input of data-write multiplexer 22. The other data input of the data-write multiplexer 22 is coupled to the output (Q) of the flip-flop 12. The control input of data-write multiplexer 22 is driven by an AND gate 24 having a first input coupled to a write-enable line 26 from the processor bus interface 18 and a second input coupled to a factory_test_mode line 28 from the system controller interface 30.

The set (S) input of the flip-flop 12 is driven by a NAND gate 32 having a first input coupled to a factory_NVM_bit line 34 from the system controller interface 30, and a second input (inverted) coupled to a system reset (sysreset_n) line 36 from a reset controller interface 38. It is to be understood that the term “flash” is meant as a particular non-limiting embodiment of a non-volatile memory. The reset (R) input of the flip-flop 12 is driven by a NAND gate 40 having a first (inverted) input coupled to the factory_NVM_bit line 34 from the system controller interface 30, and a second input (inverted) coupled to the system reset (sysreset_n) line 36 from the reset controller interface 38.

In FIG. 1 (RW-F), one of either the asynchronous set or clear of the flip-flop (configuration register bit) is asserted during reset to the value specified by the factory NVM bit. In factory mode only, this bit may also be overwritten for manufacturing test purposes. In a factory test mode, data can be written to flip-flop 12 from the processor bus interface write_data_bus bit 20 through data-write multiplexer 22 using the factory_test_mode line 28 as a write-enable signal.

During normal operation of the FPGA, flip-flop 12 is controlled using the clock input (Clk), the data input (D), and the write_enable 26 and write_data_bus 20 signals through data-write multiplexer 22.

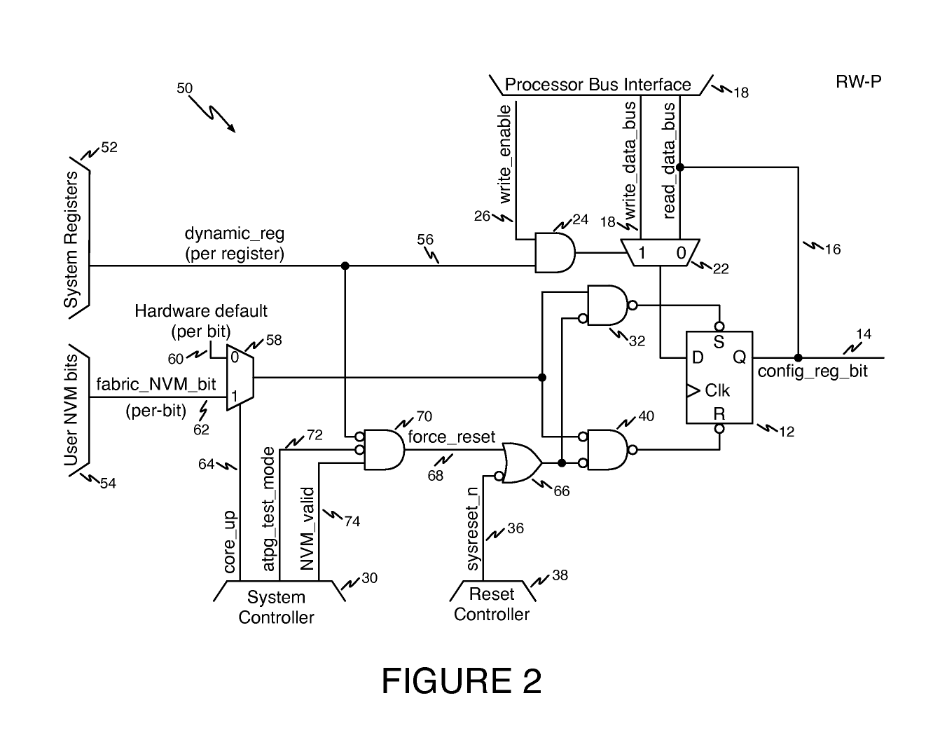

Referring now to FIG. 2, a block diagram shows an illustrative embodiment of an RW-P register 50 according to one aspect of the present invention. The elements of the RW-P register 50 that are the same as the elements of the RW-F register 10 of FIG. 1 are identified by the same reference numerals used for those elements in FIG. 1.

The RW-P register 50 of FIG. 2 employs signals from system registers 52 and U NVM bits 54 in addition to signals from processor bus interface 18, system controller interface 30, and system reset (sysreset_n) line 36. AND gate 24, driving the select input of the data-write multiplexer 22, receives its second input from a per-register bit on line 56 from system registers 52.

In addition, the first inputs of NAND gates 32 and 40, controlling the set (S) and reset (R) inputs of flip-flop 12, are driven by a multiplexer 58 instead of from the factory_NVM_bit line 34 from the system controller interface 30 as shown in FIG. 1. A first data input of multiplexer 58 is driven from a hardware default bit 60 (unique per bit). A second data input of multiplexer 58 is driven from a user U NVM bit (fabric_NVM _bit) 62 from U NVM bits interface 54. The control input of multiplexer 58 is driven by a core_up signal 64 from system controller interface 30. The core_up signal 64 is asserted by the system controller after the FPGA programming has been completed.

The second inputs of NAND gates 32 and 40 are driven from the output of OR gate 66 instead of directly from sysreset_n signal 36 from reset controller 38. This allows a reset to be generated from sysreset_n signal 36 through OR gate 66 or from a force_reset signal 68 at an output AND gate 70. A first (inverted) input of AND gate 70 is driven by the per-register bit on line 56 from system registers 52. A second (inverted) input of AND gate 70 is driven by an atpg_test_mode signal 72 from system controller 30. This signal is asserted during manufacturing test, which has the effect of ensuring that the flip flop (12) is not reset or set by the state of the NVM bit during manufacturing test. This allows the register to be tested independently of the NVM bit setting. A third input of AND gate 70 is driven by a NVM_valid signal 74 from the system controller 30. The NVM_valid signal 74 is asserted by the system controller 30 after the contents of the NVM memory are valid.

In the RW-P register depicted in FIG. 2, one of either the asynchronous set (S) or reset (R) of the flip-flop (system register bit) is asserted during reset to the value specified by the FPGA fabric NVM bit. However, this only happens if the FPGA fabric is programmed, which is indicated by the assertion of the core_up signal 64. If the FPGA fabric is not programmed (core_up 64 negated), then the register bit is asynchronously set or cleared based on a hardware default value for that bit 60 at the first data input of multiplexer 58. The core_up signal 64 is also an indication that the FPGA fabric is powered off, such as for a power save mode. Using this, the register circuit of FIG. 2 continues to store the value originally loaded after reset, even when the device enters power-save mode. Furthermore, this register bit may be overwritten by the processor to a new value through multiplexer 22, if desired.

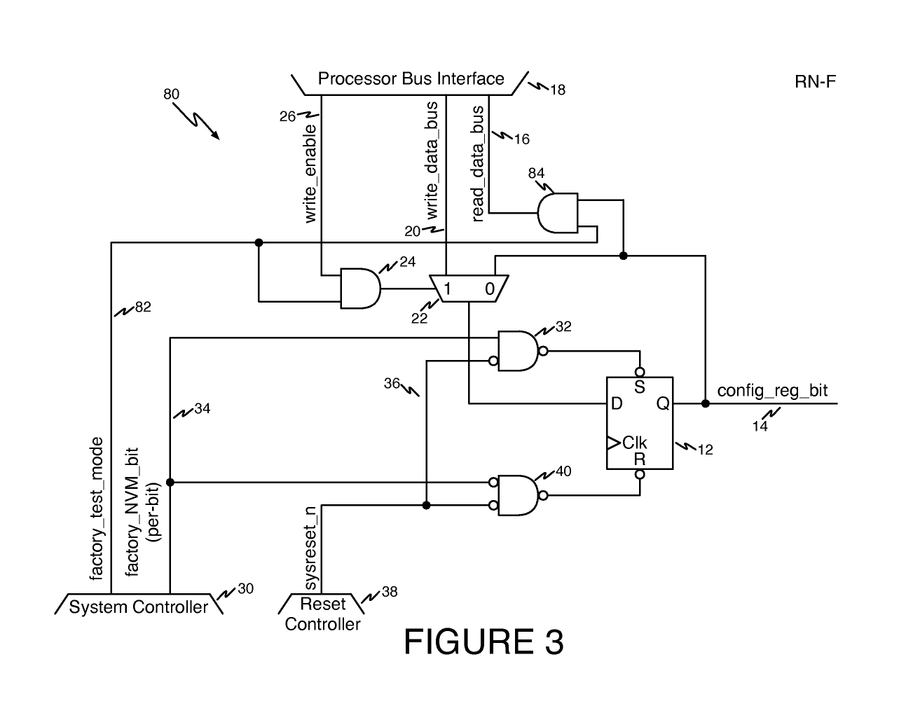

Referring now to FIG. 3, a block diagram shows an illustrative embodiment of an RN-F register 80 according to one aspect of the present invention. The elements of the RN-F register 80 that are the same as the elements in the RW-F register of FIG. 1 are identified by the same reference numerals used for those elements in FIG. 1.

The RN-F register 80 of FIG. 3 differs from the RW-P register 50 of FIG. 2 in two respects. First, the second input of AND gate 24 is driven by a factory_test_mode signal 82 from the system controller interface 30. In addition, the read_data signal 16 of the processor bus interface 18 is driven by AND gate 84, which has a first input driven by the configuration register bit (config_reg_bit) 14 and a second input driven by the factory_test_mode signal 82 from the system controller interface 30.

In the RNF register 80 of FIG. 3, one of either the asynchronous set or clear of the flip-flop 12 (configuration register bit) is asserted during reset to the value specified by the factory_NVM_bit 34. In factory mode only, this bit may also be overwritten for manufacturing test purposes. In a factory test mode, data can be written to flip-flop 12 from the processor bus interface write_data_bus bit 20 through data-write multiplexer 22 using the factory_test_mode line 82 and write_enable line 26 to select the data through to the (D) input of the flip flop 12.

During normal operation of the FPGA, flip-flop 12 is controlled using the clock input (Clk), the data input (D), with the config_reg_bit 14 being fed back around through the multiplexer 22. This ensures that the D input never changes in normal operation.

In manufacturing test mode, the host processor may read the config_reg_bit 14 output value of the flip flop via 12 AND gate 84. However, in normal mode, the value on the factory_test_mode line 82 ensures that this AND gate 84 is gated off and so the value of config_reg_bit is not readable by the host processor.

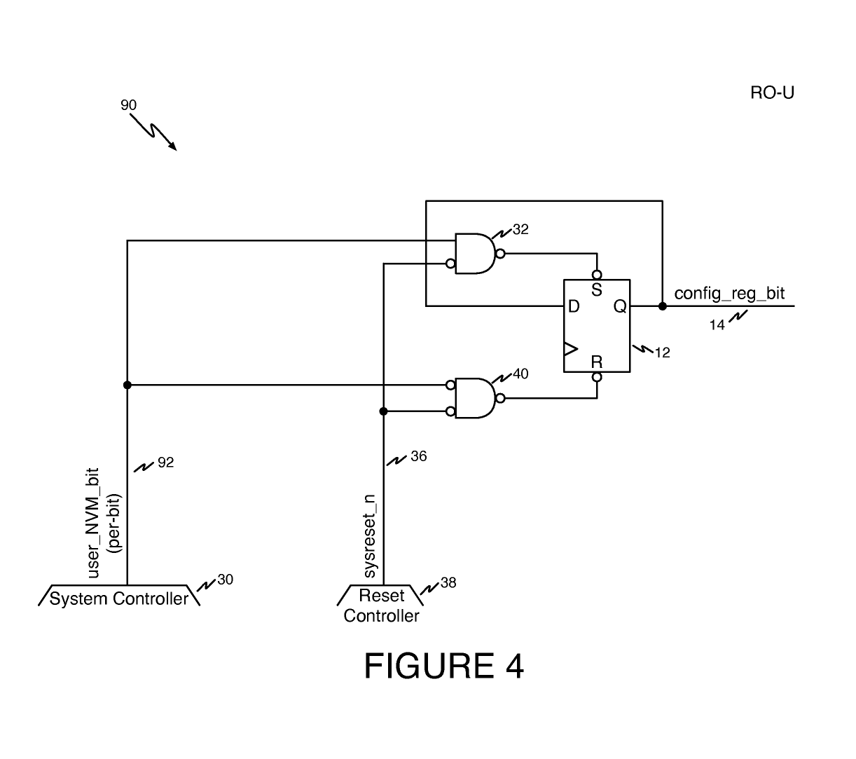

Referring now to FIG. 4, a block diagram shows an illustrative embodiment of an RO-U register 90 according to one aspect of the present invention. The elements of the RO-U register 90 that are the same as the elements of the RW-F register 10 of FIG. 1 are identified by the same reference numerals used for those elements in FIG. 1.

The RO-U register 90 of FIG. 4 is basically a subset of the RW-F register 10 of FIG. 1. The difference between the portion of the RW-F register 10 of FIG. 1 shown in FIG. 4 and the corresponding portion of the RW-F register of FIG. 1 is that the first inputs of NAND gates 32 and 40 controlling the set (S) and reset (R) inputs of flip-flop 12 are driven by a unique user_NVM_bit 92 from the system controller 30. The user_NVM_bit 92 is not a NVM bit from the FPGA fabric (the signal on line 62 in FIG. 2) but is rather an NVM bit associated with a separate memory block which has security protection. These NVM bits cannot be erased or re-programmed unless a valid authentication key is used.

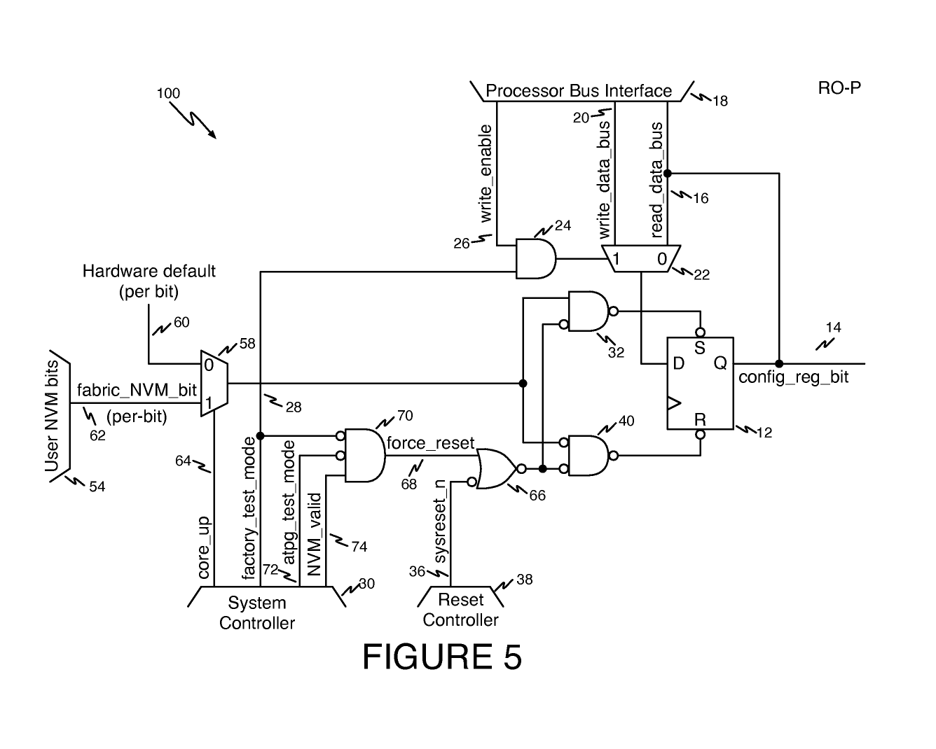

Referring now to FIG. 5, a block diagram shows an illustrative embodiment of an RO-P register 100 according to one aspect of the present invention. The RO-P register 100 of FIG. 5 includes some features of the RW-F register 10 of FIG. 1 and some features of the RW-P register 50 of FIG. 2. The elements of the RO-P register 100 that are the same as the elements of the RW-F register 10 of FIG. 1 are identified by the same reference numerals used for those elements of the RW-F register 10 in FIG. 1, and the elements of the RO-P register 100 that are the same as the elements of the RW-P register 50 of FIG. 2 are identified by the same reference numerals used for those elements of the RW-P register 50 in FIG. 2.

The RO-P register 100 of FIG. 5 includes the use of the more complex reset circuitry of FIG. 2 including OR gate 66 and AND gate 70. Like the circuit of FIG. 2, the first inputs of NAND gates 32 and 40 are driven from the output of multiplexer 58. The difference between the reset scheme of the RO-P register of FIG. 5 and the RW-P register of FIG. 2 is that, in the RO-P register of FIG. 5, the first input of AND gate 70 is driven by the factory_test_mode signal 28 from the system controller that is also used to drive the second input of AND gate 24 that drives the write-enable multiplexer 22.

In the RO-P register 100 depicted in FIG. 5, one of either the asynchronous set (S) or reset (R) of the flip-flop 12 (system register bit) is asserted during reset to the value specified by the FPGA fabric_NVM_bit 62. However, this only happens if the FPGA fabric is programmed, which is indicated by the assertion of the core_up signal 64. If the FPGA fabric is not programmed (core_up 64 negated), then the register bit is asynchronously set or cleared based on a hardware default value for that bit 60 at the first data input of multiplexer 58. The core_up signal 64 is also an indication that the FPGA fabric is powered off, such as for a power-save mode. Using this, the register circuit of FIG. 2 continues to store the value originally loaded after reset, even when the device enters power-save mode.

During normal operation of the FPGA, flip-flop 12 is controlled using the clock input (Clk), the data input (D), with the config_reg_bit 14 being fed back around through the multiplexer 22. This ensures that the (D) input never changes in normal operation.

In manufacturing test mode, the host processor may read the config_reg_bit 14 output of the flip flop 12 via AND gate 24. However, in normal mode, factory_test_mode 28 ensures that this AND gate is gated off and so the value of config_reg_bit 14 is not readable by the host processor.

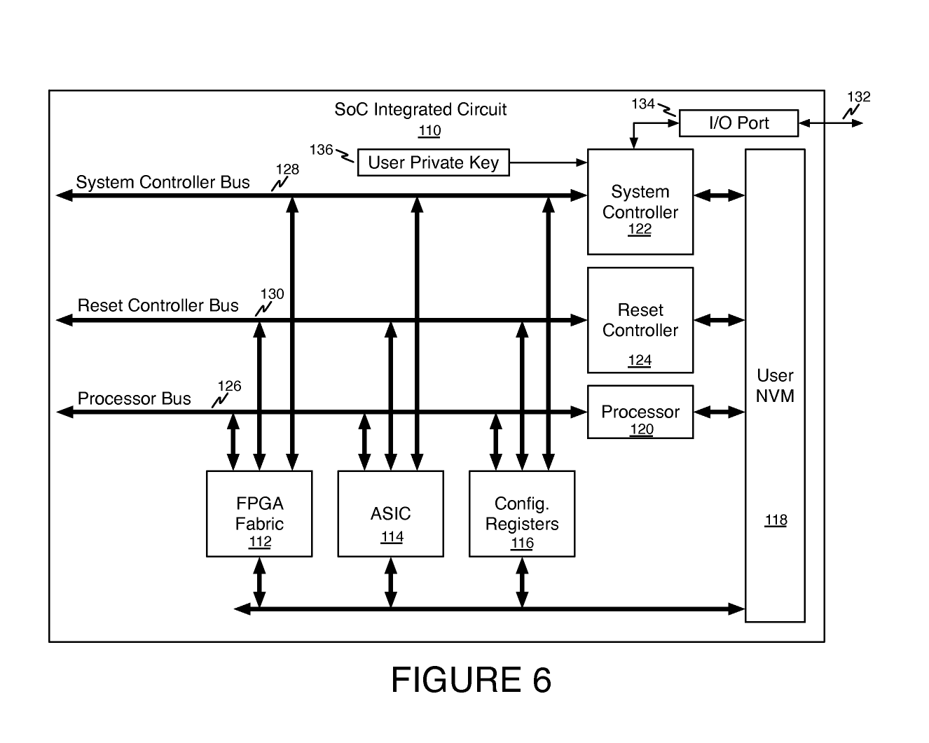

Referring now to FIG. 6, a block diagram shows an illustrative architecture for an SoC integrated circuit 110, including the configuration registers of the present invention. SoC integrated circuit 110 includes an FPGA fabric 112 that may be user configured, as is well known in the art. SoC integrated circuit 110 also includes an ASIC portion 114. A plurality of configuration registers 116 (such as those depicted in any of FIGS. 1 through 5 herein) are associated with the ASIC portion of SoC integrated circuit 110. A U NVM memory array 118 or other NVM memory, without limitation, is available for use by the FPGA fabric 112, the ASIC portion 114, the plurality of configuration registers 116, the processor 120, the system controller 122 and a reset controller 124.

SoC integrated circuit 110 also includes a processor 120. Processor 120 is hardwired on the SoC integrated circuit 110. SoC integrated circuit 110 also includes a system controller 122 and reset controller 124. System controller 122 controls the operation of the SoC integrated circuit 110, and reset controller 124 controls the reset operation of the SoC integrated circuit 110.

Processor 120 is interfaced to the FPGA Fabric 112, the ASIC portion 114, and the configuration registers 116 by a processor bus 126. System controller 122 is interfaced to the FPGA fabric 112, the ASIC portion 114, and the configuration registers 116 by a system controller bus 128. Reset controller 124 is interfaced to the FPGA fabric 112, the ASIC portion 114, and the configuration registers 116 by reset controller bus 130.

A programming bit stream 132 can typically enter the SoC integrated circuit 110 via an I/O port such as a JTAG or SPI interface, shown at reference numeral 134. A user private key at reference numeral 136 is an authentication key defined by the system integrator and is loaded into the SoC integrated circuit 110 and can be used by the system integrator to configure the device with certain security-related settings that it does not want its own customer (the end-user) to be able to modify. The U NVM bits are locked to this authentication key defined by the system integrator. Because the customer of the system integrator (the end-user) will not have access to this key, it is not possible for the end-user to override these configurations. A user public key can be included in the programming bit stream 132 and is authenticated by system controller 122 using the stored user private key at reference numeral 136. Only if the authentication is successful can the U NVM bits in the programming bit stream be erased or re-programmed.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims.

1. A method for implementing an instant boot function in a customizable system on a chip (SoC) integrated circuit having an application specific integrated circuit portion including configuration registers, comprising:
providing a field programmable gate array fabric on the SoC integrated circuit;
providing non-volatile memory cells on the SoC integrated circuit; and
initializing the configuration registers using data from the non-volatile memory cells during a system reset mode of operation of the SoC integrated circuit.

2. The method of claim 1, further comprising programming at least one of the non-volatile memory cells with data at the time of manufacture of the integrated circuit.

3. The method of claim 1, further comprising:
enabling programming of at least one of the non-volatile memory cells with data by entering a key into the SoC integrated circuit; and
programming the at least one of the non-volatile memory cells with data after enabling programming of the at least one of the non-volatile memory cells.

4. The method of claim 1, further comprising:
identifying at least one user-programmable non-volatile memory cell;
accepting programming data from a user for the at least one of the user-programmable non-volatile memory cells; and
programming the at least one of the user-programmable non-volatile memory cells with the programming data accepted from the user.

5. The method of claim 1, further comprising:
providing a factory test mode on the SoC integrated circuit; and
accepting write access commands and factory test mode data in the SoC integrated circuit from test software while in factory test mode,
wherein initializing the configuration registers using data from the non-volatile memory cells during a system reset mode of operation of the SoC integrated circuit is performed only if the SoC integrated circuit is not in the factory test mode, and initializing the configuration registers using data from the factory test mode data during the system reset mode of operation of the SoC integrated circuit if the SoC integrated circuit is in the factory test mode.

6. The method of claim 4, further comprising:
providing a dynamic register associated with at least one of the configuration registers; and
inhibiting initializing the at least one of the configuration registers if the dynamic register contains a preselected logic level.

7. The method of claim 4, further comprising:
determining during the reset mode of operation whether a programming operation for a field programmable gate array section of the SoC integrated circuit has been completed; and
initializing the configuration registers using data from the non-volatile memory cells during a system reset mode of operation of the SoC integrated circuit only after the field programmable gate array section of the SoC integrated circuit has been programmed.

8. The method of claim 7, wherein at least one of the configuration registers is writable during normal operation of the SoC integrated circuit.
